(19) United States
(12) Patent Application Publication
(10) Pub. No.: US 2024/0158914 A1
(43) Pub. Date: May 16, 2024

(54) METHOD AND USE RELATED TO A FILM AND A FILM

(71) Applicant: BENEQ OY, Espoo (FI)

(72) Inventors: Ville MALINEN, Espoo (FI); Paloma RUIZ, Espoo (FI)

(21) Appl. No.: 18/550,700

(22) PCT Filed: Mar. 18, 2022
(86) PCT No.: PCT/FI2022/050173

§ 371 Date: Sep. 15, 2023

(30) Foreign Application Priority Data
Mar. 19, 2021 (FI) 20215305

(51) Int. Cl. C23C 16/455; C23C 16/08; C23C 16/18; C23C 16/30; C23C 16/40

(52) U.S. Cl. CPC C23C 16/45529; C23C 16/08; C23C 16/18; C23C 16/305; C23C 16/40; C23C 16/45553

(57) ABSTRACT

A method for fabricating a wear-resistant optical film on a quartz substrate, and to a wear-resistant optical film and use of a wear-resistant optical film. The wear-resistant optical film includes a zinc sulphide layer on a first titanium oxide layer, the wear-resistant optical film arranged on the quartz substrate, the first titanium oxide layer improving the adhesion of the wear-resistant optical film to the quartz substrate. The method includes a) first, depositing the first titanium oxide layer on the quartz substrate with ALD and at least two precursors, and b) depositing the zinc sulphide layer on the first titanium oxide layer with ALD and at least two precursors. A wear-resistant optical film and use thereof are also disclosed.

### FIELD OF THE INVENTION

The present invention relates to a method for fabricating a wear-resistant optical film on a quartz substrate. The present invention also relates to a wear-resistant optical film on a quartz substrate and use of a wear-resistant optical film on a quartz substrate.

### BACKGROUND OF THE INVENTION

In the prior art, zinc sulphide (chemical formula ZnS, also called “ZnS” in the present text) is an important optical material used extensively as a window for visible optics applications and infrared optics applications. ZnS has good transmission characteristics with low attenuation from visible wavelengths (λ; in the order of 380 nm-750 nm) up to 12 μm in infrared (IR) wavelengths, making it an excellent window or a cover for many optical applications. The ZnS may also be patterned to provide various diffractive optics units. ZnS has a high refractive index (n=2.2 when λ=9 μm), which yields large reflection losses in optical windows. For this reason, a zinc sulphide surface is often coated with an index matching layer structure that cuts down the reflections.

In optical applications, ZnS is often deposited on a quartz substrate. Quartz has also excellent optical properties (low attenuation up to wavelengths of λ=3 μm). Optical applications comprising ZnS over a quartz substrate include micro-channel plates (MCPs) that may be used in in detection of single particles (for example, electrons) and low intensity radiation arriving on the plate (for example ultraviolet radiation and X-rays). Micro-channels are readily provided into the ZnS surface. A microchannel plate is a planar 3D object made from highly resistive material. To provide a microchannel plate, a regular array of tiny tubes or slots (microchannels) leading from one face to the opposite are arranged into a planar 3D object, and densely distributed over the whole surface. The microchannels may be 5-15 micrometers in diameter and spaced apart 10-20 micrometers and placed parallel to each other. The channels are often arranged at a small angle to the planar surface (for example, 6°-10° from normal).

Another example application for ZnS over a quartz substrate is a meta-lens where electromagnetic radiation, for example visible light, is directed by a diffractive response of the radiation to nanostructures (also called nano-antennas), said nanostructures built on or into a surface of the substrate material. Said nanostructures may also be provided into a ZnS layer over a quartz substrate in meta-lens applications.

Nanostructures over a substrate are often called “meta-materials” in the art. Meta-material comprises a nano-scale structure having individual features in the scale of some nanometers to tens of nanometers. Thus, electromagnetic properties of meta-material are arranged through the structure of the meta-material rather than directly from its molecular composition (for example, crystal lattice) or its macroscopic shape (for example, the 3D surface shape of a refractive lens).

However, in the prior art, a ZnS layer over a quartz substrate has challenges. Durability of the ZnS-quartz interface is not very good. This is manifested by low damage threshold, easy peeling off and poor resilience to water or water vapour exposures.

Thus, in prior art, wear-resistance of the ZnS film on a quartz substrate is a problem. In the present text, wear-resistance is the ability of the ZnS layer (and potentially the one or more additional layers deposited on the ZnS film) to withstand environmental factors like moisture and forces that tend to peel off the ZnS layer or parts of it off from the quartz substrate.

### BRIEF DESCRIPTION OF THE INVENTION

An object of the present invention is to provide a method for depositing a wear-resistant optical film, a wear-resistant optical film and a use of a wear-resistant optical film to overcome or at least alleviate the problems of the prior art.

The objects of the invention are achieved by a method which is characterized by what is stated in the independent claim 1. The objects of the invention are further achieved by a film which is characterized by what is stated in the independent claim 19. The objects of the invention are further achieved with use of a film which is characterized by what is stated in the independent claim 25.

The preferred embodiments of the invention are disclosed in the dependent claims.

As an aspect of the invention, a method for fabricating a wear-resistant optical film on a quartz substrate is disclosed. The wear-resistant optical film comprises a zinc sulphide layer and a first titanium oxide layer. The zinc sulphide layer is arranged on the first titanium oxide layer, and the wear-resistant optical film is arranged on the quartz substrate. The first titanium oxide layer is arranged to improve the adhesion of the wear-resistant optical film to the quartz substrate. The method comprises the steps of a) first, depositing the first titanium oxide layer on the quartz substrate with alternately repeating surface reactions of at least two precursors, including a precursor for titanium and a first precursor for oxygen for forming the first titanium oxide layer, and b) after step a), depositing the zinc sulphide layer on the first titanium oxide layer with alternately repeating surface reactions of at least two precursors, including a precursor for zinc and a precursor for sulphur for forming the zinc sulphide layer.

Advantage of the method is that wear-resistance and adhesion of the ZnS layer is improved. With the method and the first titanium oxide layer deposited in the method, the tendency of the ZnS layer to peel off or delaminate is lessened when the ZnS layers is exposed to mechanical wear or to moisture, or to both mechanical wear and moisture.

In an embodiment, the wear-resistant optical film comprises a second titanium oxide layer and an aluminium oxide layer. The second titanium oxide layer is arranged on the aluminium oxide layer, and the aluminium oxide layer is arranged on the zinc sulphide layer. The second titanium oxide layer and the aluminium oxide are arranged to decrease the water permeability the of the wear-resistant optical film. The method comprises further the steps of c) after step b), depositing the aluminium oxide layer on the zinc sulphide layer with alternately repeating surface reactions of at least two precursors including a precursor for aluminium and a second precursor for oxygen for forming the aluminium oxide layer, and d) after step c), depositing the second titanium oxide layer on the aluminium oxide layer with alternately repeating surface reactions of at least two precursors including the precursor for titanium and the first precursor for oxygen for forming the second titanium oxide layer.

Advantage of the embodiment is that the aluminium oxide layer blocks moisture penetration to the structure even further, and thus acts a moisture barrier. The aluminium oxide layer is also provided for optical index matching. The second titanium oxide layer is also arranged as a moisture barrier.

In an embodiment, the precursor for titanium is selected from a group consisting of titanium chloride, titanium bromide, and titanium iodide. These are cost effective precursors with good reactivity.

In an embodiment, the precursor for titanium is selected from a group consisting of titanium ethoxide, titanium i-propoxide, and titanium t-butoxide. These precursors have good reactivity in lower deposition temperatures (for example less than 200° C.).

In an embodiment, the precursor for titanium is selected from a group consisting of tetrakis(dimethylamino)titanium, tetrakis(diethylamino)titanium, and tetrakis(ethylmethylamino)titanium. These precursors have good reactivity in lower deposition temperatures (for example, less than 200° C.).

In an embodiment, the precursor for aluminium is selected from a group consisting of tri-methyl-aluminium, aluminium tri-chloride, aluminium isopropoxide, and tris(dimethylamido)aluminium(III). These are cost effective precursors with good reactivity.

In an embodiment, the precursor for sulphur is selected from a group consisting of hydrogen sulphide, di-tert-butyl disulphide, and elemental sulphur vapour. These are cost effective precursors with good reactivity.

In an embodiment, the precursor for zinc is selected from a group consisting of bis(pentafluorophenyl)zinc, bis(2,2,6,6-tetramethyl-3,5-hepta-nedionato)zinc(II), diethylzinc and diphenylzinc. Diethylzinc and diphenylzinc are cost effective precursors with good reactivity. Bis(pentafluorophenyl)zinc and bis(2,2,6,6-tetramethyl-3,5-hepta-nedionato)zinc(II) are advantageous in lower deposition temperatures (for example less than 200° C.).

In an embodiment, the first precursor for oxygen is selected from a group consisting of water, methanol, ethanol, propanol, isopropanol, butanol, 2-butanol, and tert-butanol. These are cost effective precursors with good reactivity.

In an embodiment, the first precursor for oxygen is selected from a group consisting of ozone, and a combination comprising ozone. Ozone is a highly reactive gas that often achieves a high deposition rate (in the present text, “a deposition rate” means the average thickness of film grown in one deposition cycle).

In an embodiment, the first precursor for oxygen is selected from a group consisting of a combination of ozone and water, a combination of ozone and oxygen, and a combination of ozone and hydrogen peroxide. Combining ozone with other precursors is advantageous in controlling the deposition rate.

In an embodiment, the first precursor for oxygen is selected from a group consisting of oxygen-containing radicals, oxygen plasma, carbon dioxide plasma, organic peroxides, organic hydroperoxides, peroxyacids, and singlet oxygen. Plasma is also highly reactive and provides a high deposition rate.

In an embodiment, the second precursor for oxygen is selected from a group consisting of water, methanol, ethanol, propanol, isopropanol, butanol, 2-butanol, and tert-butanol. These are cost effective precursors with good reactivity.

In an embodiment, the second precursor for oxygen is selected from a group consisting of ozone; and a combination comprising ozone. Ozone is a highly reactive gas that often achieves a high deposition rate

In an embodiment, the second precursor for oxygen is selected from a group consisting of a combination of ozone and water, a combination of ozone and oxygen, and a combination of ozone and hydrogen peroxide. Combining ozone with other precursors is advantageous in controlling the deposition rate.

In an embodiment, the second precursor for oxygen is selected from a group consisting of oxygen-containing radicals, oxygen plasma, carbon dioxide plasma, organic peroxides, organic hydroperoxides, peroxyacids, and singlet oxygen. Plasma is also highly reactive and provides a high deposition rate.

In an embodiment, the steps of depositing the first titanium oxide layer and depositing the zinc sulphide layer are carried out at a temperature of 60-450° C.; or more preferably 65-250° C.; or most preferably 70-150° C. These ranges are advantageous for a variety of precursors. It is especially advantageous to make the depositions with modest temperatures for optical purposes.

In an embodiment, the steps of depositing the aluminium oxide layer and depositing the second titanium oxide layer are carried out at a temperature of: 60-450° C.; or more preferably 65-250° C.; or most preferably 70-150° C. These ranges are advantageous for a variety of precursors. It is especially advantageous to make the depositions with modest temperatures for optical purposes.

In an embodiment, depositing the first titanium oxide layer is carried out until the thickness of the first titanium oxide layer is 1-10 nm (nanometer); or more preferably 2-6 nm; or most preferably 3-4 nm. It is advantageous to keep the first titanium oxide layer providing the increased adhesion very thin as a thin layer affects the optical performance minimally. When depositing layers that are approximately 10-100 atoms or molecules thick, corresponding to approximately 1-10 nm thickness, it is advantageous to ascertain that a continuous layer is arranged. In almost all deposition regimes corresponding to certain deposition temperatures and precursors, at a thickness of 3 nm uniformity and continuity of the layer is often certain, and deposition is already uniform, and a continuous film is provided.

In an embodiment, depositing the zinc sulphide layer is carried out until the thickness of the zinc sulphide layer is 10-500 nm; or more preferably 50-400 nm; or most preferably 100-300 nm. These thickness ranges are advantageous for providing various optical applications like a meta-lens or another meta-material and at the same time providing short deposition times.

In an embodiment, depositing the aluminium oxide layer is carried out until the thickness of the aluminium oxide layer is 100-300 nm; or more preferably 150-250 nm; or most preferably 175-225 nm. These thickness ranges are advantageous for refractive index matching and to arrange a moisture barrier such that deposition times are short.

In an embodiment, depositing the second titanium oxide layer is carried out until the thickness of the second titanium oxide layer is: 1-15 nm; or more preferably 4-10 nm; or most preferably 5-8 nm. A very thin second titanium oxide layer as a capping layer is often sufficient to arrange a moisture barrier with minimal deposition time and minimal negative impact on the optical qualities.

As an aspect of the present invention, a wear-resistant optical film on a surface of a quartz substrate is obtained by a method as described above in the method aspect of the invention, and its embodiments. The indicated method provides uniform, repeatable and pin-hole free films that markedly increase adhesion and ability to withstand moisture of the wear-resistant optical film.

As an aspect of the present invention, a wear-resistant optical film on a surface of a quartz substrate comprises a zinc sulphide layer and a first titanium oxide layer. The zinc sulphide layer is provided on the first titanium oxide layer, and the first titanium oxide layer is provided on the quartz substrate. This structure markedly improves the wear-resistance when wear-resistance is determined by adhesion and ability to withstand moisture.

In an embodiment, the wear-resistant optical film comprises an aluminium oxide layer deposited on the zinc sulphide layer and a second titanium oxide layer deposited on the aluminium oxide layer. This structure improves the wear-resistance even more at least when wear-resistance is determined by adhesion and ability to withstand moisture. Aluminium oxide layer provides also refractive index matching for light in optical applications.

In an embodiment, the thickness of the first titanium oxide layer is 1-10 nm; or more preferably 2-6 nm; or most preferably 3-4 nm. A very thin film is advantageous to minimize optical negative effects like light attenuation and light reflections at the media interfaces as a very thin film is sufficient to improve wear-resistance (adhesion and ability to withstand moisture) markedly.

In an embodiment, the thickness of the zinc sulphide layer is 10-500 nm; or more preferably 50-400 nm; or most preferably 100-300 nm. These thickness ranges are advantageous for arranging various optical applications like meta-materials, for example a meta-lens, such that deposition times do not grow excessive.

In an embodiment, the thickness of the aluminium oxide layer is 100-300 nm; or more preferably 150-250 nm; or most preferably 175-225 nm. These thickness ranges are advantageous for refractive index matching and to arrange a moisture barrier such that deposition times do not grow excessive.

In an embodiment, the thickness of the second titanium oxide layer is 1-15 nm; or more preferably 4-10 nm; or most preferably 5-8 nm. A very thin second titanium oxide layer as a capping layer is often sufficient to arrange a moisture barrier with minimal deposition time and minimal negative impact on the optical qualities.

As an aspect of the invention, use of a wear-resistant optical film on at least one quartz substrate is disclosed. The wear-resistant optical film is defined in the wear-resistant optical film aspect of the current invention, and its embodiments. At least one quartz substrate comprises at least one quartz area, and the at least one quartz area is arranged at an outer surface of an optical device. The wear-resistant optical film is used for protecting the at least one quartz area against detrimental effects of environment. The optical device may be for example a meta-lens where the nano-structure of the lens is arranged into the ZnS layer. With the use of the wear-resistant optical film, adhesion and ability to withstand moisture of the zinc sulphide layer is improved if zinc sulphide is to be deposited on the quartz area.

The invention is based on the idea of arranging a titanium oxide layer as the adhesion layer between the quartz substrate and the ZnS layer. Even though the adhesion layer may be arranged to be very thin and has thus negligible optical consequences, it dramatically improves the adhesion of the ZnS layer on quartz. Adhesion is improved in terms of mechanical stress or mechanical pulling force on the ZnS layer, pulling force applied outwards relative to the quartz substrate, manifested by good tape test results where the ZnS layer is attempted to be peeled off the quartz substrate. Adhesion is also improved in terms of how well the layer withstands moisture, as manifested by good water bath test results in deionized water.

An advantage of the invention is that adhesion of an ZnS layer on quartz is markedly improved, both mechanically and in terms of moisture exposure. This is advantageous especially when a ZnS/quartz interface is used in optical applications that may be exposed to environmental exposures, for example moisture, water vapour and condensation of water on the ZnS layer, and also mechanical stress that may be abrasive or tend to peel off the ZnS layer from the surface of the substrate. Said optical applications may include details in microchannel plates, meta-lenses, or other meta-materials. In general, by arranging a very thin adhesion layer of titanium oxide between the quartz substrate and the ZnS layer in an optical device, both the adhesion and resistance to moisture of the ZnS layer over quartz are markedly improved, with no measurable penalty in the optical performance in the optical device. Physical and mechanical performance in relation to adhesion and resistance to moisture can further be improved with an aluminium oxide-titanium oxide layer structure on the ZnS layer.

For the purposes of this text, “quartz” is a hard, crystalline mineral composed of silicon and oxygen atoms. In quartz, the atoms are linked in a continuous framework of SiO₄ silicon-oxygen tetrahedra. Each oxygen atom is shared between two tetrahedra. Thus, quartz has a chemical formula of SiO₂. As physical objects, quartz may be provided as a thin wafer, which is for example a circular disk having a uniform radius (for example 50 mm) and uniform thickness (for example, 350 μm), or a section of such a wafer. The section may be diced to a rectangular shape, for example.

It is also possible to deposit SiO₂ as quartz with Chemical Vapor Deposition (PECVD), sputtering, pulsed LASER deposition (PLD) or ALD (atomic layer deposition) on a surface of another carrier material to provide a quartz substrate.

It is also possible to form SiO₂ as quartz from a silicon (Si) surface by providing oxidisation on the silicon surface and then provide annealing to arrange the SiO₂ into crystal form of quartz to provide a quartz substrate.

Quartz substrate comprises a quartz surface which may also be patterned for example by etching.

As with any real and practical substance, impurity atoms, lattice discontinuities and other nonidealities may be present in quartz in trace amounts.

For the purposes of this text, any quartz layer or article provided by a quartz object like a wafer or a diced wafer, deposited layer of quartz on a carrier material, or oxidised surface layer of silicon (Si) article, such that silicon is oxidised and annealed into quartz at the surface layer of silicon article, is called a “quartz substrate”. Surface of the quartz substrate may be planar, uniform or patterned into any three-dimensional shape or patterned into any number of three-dimensional shapes.

For the purposes of this text, unless otherwise stated, an “ALD process” or shortly “ALD” is a method for depositing uniform and conformal deposits or layers over substrates of various shapes that may be planar, wafer-like, but that may also be complex three-dimensional structures. In ALD (ALD is abbreviation for atomic layer deposition), the surface of the substrate (or the surface of a layer already deposited on the substrate) is alternately exposed to at least two different precursors (chemicals) in gas phase (or vapour phase), usually one precursor at a time, to form a deposit or a layer by alternately repeating essentially self-limiting surface reactions between the surface and the precursors. As a result, the deposited material is “grown” molecule layer by molecule layer on the substrate, or on a previous layer deposited on the substrate. In other words, in ALD a layer is deposited on a surface of an article with alternately repeating surface reactions of at least two precursors.

In many ALD processes, the exposure of the substrate to the precursor is arranged in low pressure conditions, and in a reaction chamber arranged inside a vacuum chamber of a deposition tool to provide low-pressure conditions. Purpose of the reaction chamber is to isolate the reaction process and the build-up of potential residue and other unwanted soiling due to deposits in unwanted areas and make the cleaning of the deposition tool easier. The reaction chamber may also be arranged as the carrier or holder or rack for the articles to be coated, for example substrates.

In ALD, a surface is exposed to two or more different precursors in an alternate manner with usually a purging period in between the precursor pulses. During a purging period, the surface is exposed to a flow of gas which does not react with the precursors used in the process. This gas, often called the “carrier gas”, “inert gas” or “purge gas” is therefore inert towards the precursors and surfaces used in the process and removes a surplus precursor and by-products resulting from the chemisorption reactions of the previous precursor pulse. This purging can be arranged by different means and processes. The basic requirement of the ALD-type process is that the deposition surface is purged between the introduction of a precursor for a metal and a precursor for a non-metal. The purging period ensures that the gas phase growth is limited and only surfaces exposed to the precursor gas participate in the growth.

The alternate or sequential exposure of the deposition surface to different precursors can be carried out in different manners. In a batch type process at least one substrate is placed in a reaction space, into which precursor and purge gases are being introduced in a predetermined cycle. Spatial atomic layer deposition is an ALD-type process based on the spatial separation of precursor gases or vapours. The different precursor gases or vapours can be confined in specific process areas or zones while the substrate goes through the zones. In the continuous ALD-type process, constant gas flow zones separated in space and a moving substrate through the zones are used to obtain the sequential exposure. By moving the substrate through stationary zones, providing precursor exposure and purging areas to separate the zones spatially, in the reaction space, a continuous coating process is achieved enabling roll-to-roll coating of a substrate. In continuous ALD-type process the cycle time depends on the speed of movement of the substrate and its surface between the gas flow zones.

Other names besides atomic layer deposition (ALD) have also been employed for processes where the alternate introduction of or exposure to two or more different precursors lead to the growth of the layer, often through essentially self-limiting surface reactions. These other names or process variants include atomic layer epitaxy (ALE), atomic layer chemical vapour deposition (ALCVD), and corresponding plasma enhanced variants. Unless otherwise stated, also these processes will be collectively addressed “ALD” in the present application.

For the purposes of this text, a metal “oxide” (for example, titanium oxide or aluminium oxide) refers to all oxides of the corresponding metal of various chemical compositions, phases and crystalline structures. Correspondingly, where a stoichiometric chemical formula or name is used for an oxide, this is not meant to imply that the layer in question has the corresponding absolute stoichiometric composition. Thus, for example titanium oxide may mean TiO₂ and aluminium oxide may mean Al₂O₃.

For the purposes of this text, depositing a further layer “on” a previous layer (or underlying layer) refers to a deposition directly on the previous layer, or directly on the substrate in case of the first layer on the substrate, or directly on a quartz area in case of the first layer on the quartz area. Similarly, when a layer (layer A) is “on” another layer (layer B), it means that the layer A is directly on the other layer B.

Between any two layers, an interfacial region which has different physical characteristics than either of the two layers around it may be formed in the deposition process, for example due to crystallinity or amorphicity characteristics of the interfacial region. If such an interface structure exists, it is due to the deposition of the layer on the previous layer in the given process conditions like temperature, pressure and precursors.

The substrate may be pre-treated before the deposition, for example cleaned. As pre-treatment, a native oxide grown spontaneously on the substrate may also be removed which is advantageous if the native oxide differs from the underlying material.

### BRIEF DESCRIPTION OF THE DRAWINGS

The invention is described in detail by means of specific embodiments with reference to the enclosed drawings, in which

FIG. 1 shows a wear-resistant optical film according to an embodiment of the invention,

FIG. 2 shows a method for depositing a wear-resistant optical film according to an embodiment of the invention,

FIG. 3 shows a wear-resistant optical film according to an embodiment of the invention,

FIG. 4 shows another method for depositing a wear-resistant optical film according to an embodiment of the invention, and

FIG. 5 shows use of a wear-resistant optical film according to an embodiment of the invention.

### DETAILED DESCRIPTION OF THE INVENTION

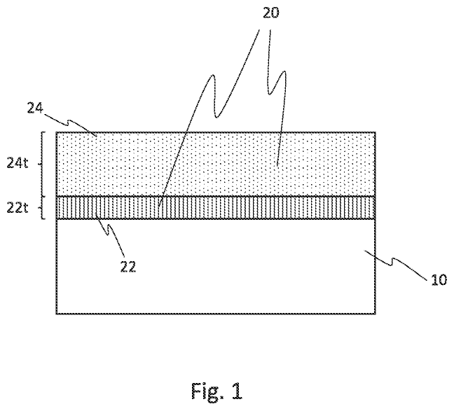

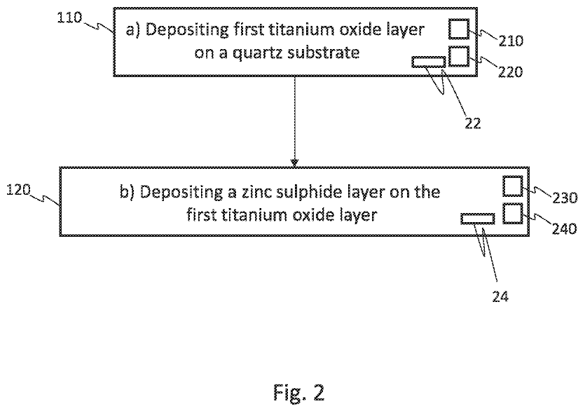

FIG. 1 shows a wear-resistant optical film 20 according to an aspect of the present invention, a method for fabricating a wear-resistant optical film 20 on a quartz substrate 10. The wear-resistant optical film 20 comprises a zinc sulphide layer 24 and a first titanium oxide layer 22, the zinc sulphide layer 24 arranged on the first titanium oxide layer 22. The wear-resistant optical film 20 is arranged on the quartz substrate 10 such that the first titanium oxide layer 22 is arranged on the quartz substrate 10. The first titanium oxide layer 22 is arranged to improve the adhesion of the wear-resistant optical film to the quartz substrate 10. Referring also to FIG. 2, the method comprises steps of a) first, depositing (show with step 110) the first titanium oxide layer 22 on the quartz substrate 10 with alternately repeating surface reactions of at least two precursors, shown with symbols 210 and 220. The at least two precursors include a precursor for titanium 210 and a first precursor for oxygen 220. The said deposition is done for forming the first titanium oxide layer 22.

Thus, the first titanium oxide layer 22 is deposited with the ALD method, with at least two precursors that include a precursor for titanium 210 and a first precursor for oxygen 220.

The method also comprises step b) performed after step a). In step b, the zinc sulphide layer 24 is deposited (shown with step 120) on the first titanium oxide layer 22 with alternately repeating surface reactions of at least two precursors 230 and 240, including a precursor for zinc (labelled as 230) and a precursor for sulphur (labelled as 240). The said deposition is done for forming the zinc sulphide layer 24.

Thus, the zinc sulphide layer 24 is deposited with the ALD method, with at least two precursors that include a precursor for zinc 230, and a precursor for sulphur 240.

For the purposes of this text, an optical film is a film which has utility in optical applications for example due to its good transparency indicated by low losses when light travels through the film or due to its strong ability to diffract or refract light (which may be indicated by a high refractive index when light is incident on the surface of the film), or both. Transmittance of the optical film may be 10%-99%, 50%-80% or 60-75% at the wavelengths the optical film is utilized.

Exact atomic level functionality and characteristics of the adhesion layer and the improved adhesion thereof provided with the first titanium oxide layer is not well understood. Without limiting the present text to any physical theory, metallic titanium is known to have good and versatile bond forming capabilities with various other substances, compounds and elements. It is possible that titanium atoms of the first titanium oxide layer may participate in bond forming with both quartz and ZnS advantageously such that overall adhesion is improved.

Advantage of the method is that wear-resistance and adhesion of the ZnS layer is improved. With the method and the first titanium oxide layer deposited in the method, the tendency of the ZnS layer to peel off or delaminate is lessened when exposed to mechanical wear and when exposed to moisture.

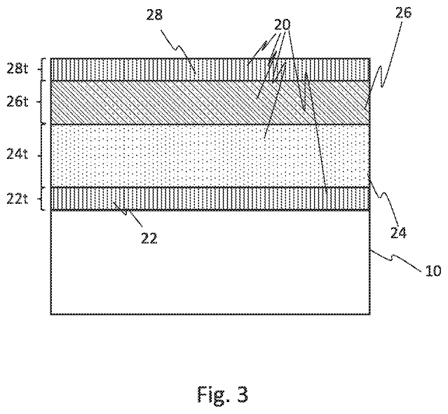

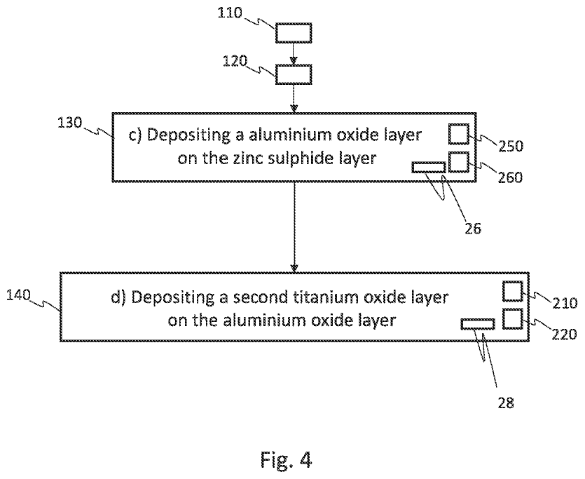

Next, referring to FIG. 3, in an embodiment the wear-resistant optical film 20 comprises further a second titanium oxide layer 28 on an aluminium oxide layer 26. The aluminium oxide layer 26 is provided on the zinc sulphide layer 24. The second titanium oxide layer 28 and the aluminium oxide layer 26 are arranged to decrease or lessen the water permeability of the wear-resistant optical film 20 even further. Referring to FIG. 4, the method comprises further the steps of c) after step b), depositing (in step 130) the aluminium oxide layer 26 on the zinc sulphide layer 24 with alternately repeating surface reactions of at least two precursors (denoted with symbols 250 and 260) including a precursor 250 for aluminium and a second precursor for oxygen 260 for forming the aluminium oxide layer 26. The method comprises also, as step d) 140 after step c), a step of depositing the second titanium oxide layer 28 on the aluminium oxide layer 26 with alternately repeating surface reactions of at least two precursors including the precursor for titanium (denoted with symbol 210) and the first precursor for oxygen (denoted with 220) for forming the second titanium oxide layer 28.

Thus, the aluminium oxide layer 26 is deposited with the ALD method, with at least two precursors that include a precursor for aluminium 250 and a second precursor for oxygen 260. The second titanium oxide layer 28 on the aluminium oxide layer 26 is also deposited with the ALD method, with at least two precursors including the precursor for titanium 210 and the first precursor for oxygen 220.

Aluminium oxide layer 26 may be arranged also for refractive index matching. As ZnS layer has very high index of refraction (n_{ZNS} may be up to 2.4), it is advantageous to match the light propagation path to the index of refraction of the surrounding media, air (n_{A}=1.0) with a layer having an index of refraction which is the geometric average of n_{A} and n_{ZNS}. approximately 1.6 which is close to the refractive index of aluminium oxide. The aluminium oxide layer 26 also decreases the water permeability of the wear-resistant optical film 20.

The second titanium oxide layer 28 may be arranged as an additional moisture barrier, primarily against water and water vapor. Aluminium oxide also blocks moisture from entering the ZnS and first titanium oxide layer. Thus, a very wear-resistant layer structure or film is provided as show in FIG. 3. The second titanium oxide layer 28 may be called a “capping layer” as it is the topmost layer as indicated in FIG. 3, sealing the layer structure or film below it very well from moisture, arranging a cap to the film. Advantage of the embodiment is that the aluminium oxide layer blocks moisture penetration to the structure even further, and thus acts a moisture barrier. The aluminium oxide layer 26 is also provided for optical index matching. The second titanium oxide layer 28 is also arranged as a moisture barrier. In other words, the aluminium oxide layer 26 and the second titanium oxide layer 28 decrease the water permeability of the wear-resistant optical film 20 further, for both water in liquid form and water in vapor form.

In an embodiment, the method comprises a patterning step comprising patterning of the zinc sulphide layer 24 between steps b) and c). The patterning step may comprise arranging an optical device on the zinc sulphide layer 24. The optical device may be based on a meta-material and may be, for example, a meta-lens.

In an embodiment, the optical device arranged in the patterning step on the zinc sulphide layer 24 may be a meta-material.

In an embodiment, the optical device arranged in the patterning step on the zinc sulphide layer 24 may be a meta-lens.

In an embodiment, the precursor for titanium 210 is selected from a group consisting of titanium chloride (TiCl₄), titanium bromide (TiBr₄) or titanium iodide (TiI₄). These so-called halide titanium precursors are cost-effective precursors with good vapor pressure characteristics in low (less than 250° C.) deposition temperatures. They have a high reactivity and a good thermal stability.

In an embodiment, the precursor for titanium 210 is selected from a group consisting of titanium ethoxide (Ti[OC₂H₅]₄), titanium i-propoxide (Ti[OCH(CH₃)₂]₄), and titanium t-butoxide (Ti[OC₄H₉]₄). These alkoxide titanium precursors are advantageous if halide residuals or by-products generated by halide titanium precursors in the ALD process are too detrimental for example as residues in the end product or in the deposition tool.

In an embodiment, the precursor for titanium 210 is selected from a group consisting of tetrakis(dimethylamino)titanium (Ti[N(CH₃)₂]₄), tetrakis(diethylamino)titanium (Ti[N(C₂H₅)₂]₄), and tetrakis (ethylmethylamino)-titanium (Ti[N(C₂H₅) (CH₃)]₄). These titanium precursors are advantageous for low-temperature ALD processes.

In an embodiment, the precursor for titanium 210 may also comprise titanium acetamidinate.

In an embodiment, the precursor for sulphur 240 is selected from a group consisting of hydrogen sulphide, di-tert-butyl disulphide and elemental sulphur vapour. Hydrogen sulphide (H₂S) is a cost-effective but highly corrosive and toxic precursor. As a safer alternative, elemental sulphur vapour (Se) may be used, but its reactivity is considerably less than what hydrogen sulphide provides.

In an embodiment, the precursor for zinc 230 is selected from a group consisting of bis(pentafluorophenyl)zinc ((C₆F₅)₂Zn), bis(2,2,6,6-tetramethyl-3,5-heptanedionato)zinc(II) (Zn(OCC(CH₃)₃ CHCOC(CH₃)₃)₂), diethylzinc and diphenylzinc ((C₆H₅)₂Zn). Diethylzinc (called usually “DEZ” in the art, chemical formula (C₂H₅)₂Zn) is a cost-effective and highly reactive precursor, but pyrophoric, requiring special care in handling.

In an embodiment, the first precursor for oxygen 220 is selected from a group consisting of water, methanol, ethanol, propanol, isopropanol, butanol, 2-butanol, and tert-butanol. Selection of the oxidising precursor may be made based on the selection of the first titanium precursor and the desired growth rate. Precursors of this embodiment are cost effective precursors with good reactivity.

In an embodiment, the first precursor for oxygen 220 is selected from a group consisting of ozone; and a combination comprising ozone. Ozone is a highly reactive gas that often achieves a high deposition rate.

In an embodiment, the first precursor for oxygen 220 is selected from a group consisting of a combination of ozone and water, a combination of ozone and oxygen, and a combination of ozone and hydrogen peroxide. Combining ozone with other precursors is advantageous in controlling the deposition rate.

In an embodiment, the first precursor for oxygen 220 is selected from a group consisting of oxygen-containing radicals, oxygen plasma, carbon dioxide plasma, organic peroxides, organic hydroperoxides, peroxyacids, and singlet oxygen. Plasma is also highly reactive and provides a high deposition rate.

In an embodiment, the precursor for aluminium 250 is selected from a group consisting of tri-methyl-aluminium (Al(CH₃)₃), aluminium tri-chloride (AlCl₃), aluminium isopropoxide (Al(OiPr)₃) and tris(dimethylamido)-aluminium(III) (Al(NMe₂)₃). These are cost-effective precursors with good reactivity. Tri-methyl-aluminium (TMA) is a highly reactive precursor even in low process temperatures, even at temperatures below 100° C.

In an embodiment, the second precursor for oxygen 260 is selected from a group consisting of water, methanol, ethanol, propanol, isopropanol, butanol, 2-butanol, and tert-butanol. Precursors of this embodiment are cost effective precursors with good reactivity.

In an embodiment, the second precursor for oxygen 260 from a group consisting of ozone; and a combination comprising ozone. Ozone is a highly reactive gas that often achieves a high deposition rate.

In an embodiment, the second precursor for oxygen 260 is selected from a group consisting of a combination of ozone and water, a combination of ozone and oxygen, and a combination of ozone and hydrogen peroxide. Combining ozone with other precursors is advantageous in controlling the deposition rate.

In an embodiment, the second precursor for oxygen 260 is selected from a group consisting of oxygen-containing radicals, oxygen plasma, carbon dioxide plasma, organic peroxides, organic hydroperoxides, peroxyacids, and singlet oxygen. Plasma is also highly reactive and provides a high deposition rate.

In an embodiment, the steps of depositing 110 the first titanium oxide layer 22, and depositing 120 the zinc sulphide layer 24 are carried out at a temperature of 60-450° C.

In an embodiment, more preferably the steps of depositing 110 the first titanium oxide layer 22, and depositing 120 the zinc sulphide layer 24 are carried out at a temperature of 65-250° C. These ranges are advantageous for a variety of precursors. It is especially advantageous to make the depositions with modest temperatures for optical purposes.

In an embodiment, most preferably the steps of depositing 110 the first titanium oxide layer 22, and depositing 120 the zinc sulphide layer 24 are carried out at a temperature of 70-150° C. These ranges are advantageous for a variety of precursors. It is especially advantageous to make the depositions for optical purposes.

In an embodiment, the steps of depositing 130 the aluminium oxide layer 26 and depositing 140 the second titanium oxide layer 28 are carried out at a temperature of 60-450° C. These ranges are advantageous for a variety of precursors. It is especially advantageous to make the depositions with modest temperatures for optical purposes.

In an embodiment, more preferably the steps of depositing 130 the aluminium oxide layer 26 and depositing 140 the second titanium oxide layer 28 are carried out at a temperature of 65-250° C. These ranges are advantageous for a variety of precursors. It is especially advantageous to make the depositions with modest temperatures for optical purposes.

In an embodiment, most preferably the steps of depositing 130 the aluminium oxide layer 26 and depositing 140 the second titanium oxide layer 28 are carried out at a temperature of 70-150° C. These ranges are advantageous for a variety of precursors. It is especially advantageous to make the depositions with modest temperatures for optical purposes.

In an embodiment, depositing 110 the first titanium oxide layer 22 is carried out until the thickness 22t of the first titanium oxide layer 22 is 1-10 nm. It is advantageous to arrange the first titanium oxide layer providing the increased adhesion to be very thin as a thin layer affects the optical performance minimally. When depositing layers that are approximately 10-100 atoms or molecules thick, corresponding to approximately 1-10 nm thickness, the growth starts as islands and as the islands merge when more film is deposited, a continuous, uniform film is provided. At 1 nm thickness (corresponding to approximately 10 atoms or molecules in thickness direction) with many precursors and temperatures, deposition is already uniform, and a continuous film is provided.

In an embodiment, more preferably depositing 110 the first titanium oxide layer 22 is carried out until the thickness 22t of the first titanium oxide layer 22 is 2-6 nm.

In an embodiment, depositing 110 the first titanium oxide layer 22 is carried out until the thickness 22t of the first titanium oxide layer 22 is 3-4 nm. In many deposition regimes corresponding to certain deposition temperatures and precursors, at a thickness between 3-4 nm, uniformity and continuity of the layer is often achieved with high certainty.

In an embodiment depositing 120 the zinc sulphide layer 24 is carried out until the thickness 24t of the zinc sulphide layer 24 is 10-500 nm. Various optical devices can be arranged to the zinc sulphide with this thickness.

In an embodiment, more preferably depositing 120 the zinc sulphide layer 24 is carried out until the thickness 24t of the zinc sulphide layer 24 is 50-400 nm. Various optical devices can be arranged to the zinc sulphide with this thickness.

In an embodiment, most preferably depositing 120 the zinc sulphide layer 24 is carried out until the thickness 24t of the zinc sulphide layer 24 is 100-300 nm. Various optical devices can be arranged to the zinc sulphide with this thickness.

In an embodiment, depositing 130 the aluminium oxide layer 26 is carried out until the thickness 26t of the aluminium oxide layer 26 is 100-300 nm. This is an advantageous thickness for refractive index matching purposes in this context.

In an embodiment, more preferably depositing 130 the aluminium oxide layer 26 is carried out until the thickness 26t of the aluminium oxide layer 26 is 150-250 nm. This is an advantageous thickness for refractive index matching purposes.

In an embodiment, most preferably depositing 130 the aluminium oxide layer 26 is carried out until the thickness 26t of the aluminium oxide layer 26 is 175-225 nm. This is an advantageous thickness for refractive index matching purposes.

In an embodiment, depositing 140 the second titanium oxide layer 28 is carried out until the thickness 28t of the second titanium oxide layer 28 is 1-15 nm. A very thin second titanium oxide layer as a capping layer is often sufficient to arrange a moisture barrier with minimal deposition time and minimal negative impact on the optical qualities.

In an embodiment, more preferably depositing 140 the second titanium oxide layer 28 is carried out until the thickness 28t of the second titanium oxide layer 28 is 4-10 nm. A very thin second titanium oxide layer as a capping layer is often sufficient to arrange a moisture barrier with minimal deposition time and minimal negative impact on the optical qualities.

In an embodiment, most preferably depositing 140 the second titanium oxide layer 28 is carried out until the thickness 28t of the second titanium oxide layer 28 is most preferably 5-8 nm. A very thin second titanium oxide layer as a capping layer is often sufficient to arrange a moisture barrier with minimal deposition time and minimal negative impact on the optical qualities.

As an aspect of the present invention, a wear-resistant optical film 20 on a surface of a quartz substrate is obtained by a method of as described above. The indicated method provides uniform, repeatable and pin-hole free films.

As an aspect of the present invention, a wear-resistant optical film 20 on a surface of a quartz substrate is disclosed. The wear-resistant optical film 20 comprises a zinc sulphide layer 24 and a first titanium oxide layer 22. The zinc sulphide layer 24 is provided (in other words, deposited) on the first titanium oxide layer 22, and the first titanium oxide layer is provided (in other words, deposited) on the quartz substrate 10. The first titanium oxide layer 22 is arranged to improve adhesion of the zinc sulphide layer 24 to the quartz substrate 10 and to the quartz surface of the quartz substrate 10. The wear-resistant optical film 20 markedly improves the wear-resistance at least when wear-resistance is determined by good adhesion and ability to withstand moisture.

In an embodiment, the wear-resistant optical film 20 comprises an aluminium oxide layer 26 and a second titanium oxide layer 28. The aluminium oxide layer 26 is deposited on the zinc sulphide layer 24, and a second titanium oxide layer 28 deposited on the aluminium oxide layer 26. This structure improves the wear-resistance even more at least when wear-resistance is determined by adhesion and ability to withstand moisture. Aluminium oxide layer provides also refractive index matching for light in optical applications.

In an embodiment, the thickness 22t of the first titanium oxide layer 22 of the wear-resistant optical film 20 is 1-10 nm. A very thin titanium oxide layer providing the increased adhesion affects the optical performance minimally. Layers that are approximately 10-100 atoms or molecules thick, correspond to approximately 1-10 nm thickness. When the layer is deposited, the growth starts as islands. When more film is deposited, the islands merge and a continuous, uniform film is provided. At 1 nm thickness (corresponding to approximately 10 atoms or molecules in thickness direction) with many precursors and temperatures, deposition is already uniform, and a continuous film is provided.

In an embodiment, more preferably the thickness 22t of the first titanium oxide layer 22 of the wear-resistant optical film 20 is 2-6 nm.

In an embodiment, most preferably the thickness 22t of the first titanium oxide layer 22 of the wear-resistant optical film 20 is 3-4 nm. This is an advantageous thickness as the uniformity of the film is often very good already at this range of 3-4 nm, and as the thickness is still very small, the first titanium oxide layer affects the optical performance minimally. Still, the wear-resistance of the wear-resistant optical film 20 is improved markedly.

In an embodiment, the thickness 24t of the zinc sulphide layer 24 of the wear-resistant optical film 20 is 10-500 nm. This is an advantageous thickness as various optical structures can be provided on this thickness range.

In an embodiment, more preferably the thickness 24t of the zinc sulphide layer 24 of the wear-resistant optical film 20 is 50-400 nm. This is an advantageous thickness as various optical structures can be provided on this thickness range.

In an embodiment, most preferably the thickness 24t of the zinc sulphide layer 24 of the wear-resistant optical film 20 is 100-300 nm. This is an advantageous thickness as various optical structures can be provided on this thickness range.

In an embodiment, the thickness 26t of the aluminium oxide layer 26 is 100-300 nm; or more preferably 150-250 nm; or most preferably 175-225 nm. These are advantageous thicknesses for index matching, arranging a moisture barrier and keeping the deposition times of the aluminium oxide layer 26 short.

In an embodiment, the thickness 28t of the second titanium oxide layer 28 is 1-15 nm; or more preferably 4-10 nm; or most preferably 5-8 nm. These are advantageous thicknesses for capping the layer structure comprising the first titanium oxide layer 22, the zinc sulphide layer 24, and the aluminium oxide layer 26. The second titanium oxide layer 28 provides an additional moisture barrier, and due to the very thin nature of the second titanium oxide layer 28, the deposition times to arrange said layer are short, and effects to optical performance of the wear-resistant optical film 20 is minimal.

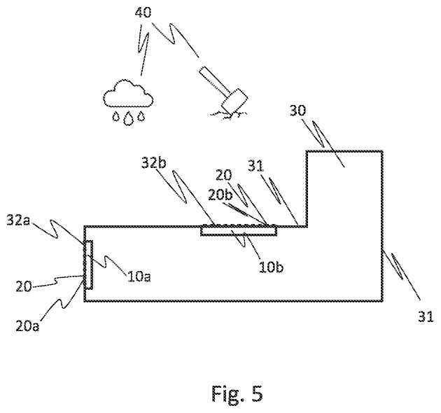

As an aspect of the present invention, referring to FIG. 5, use of a wear-resistant optical film 20 on a quartz substrate 10 as described above is disclosed. In the use, at least one quartz substrate 10 comprises at least one quartz area 32a, 32b, and the at least one quartz area 32a, 32b is arranged at an outer surface 31 of an optical device 30. The wear-resistant optical film 20 is used for protecting the at least one quartz area 32a, 32b against detrimental effects of environment, said effects marked with symbols 40. If the optical device comprises more than one quartz areas 32a, 32b, more than one wear-resistant optical films 20a, 20b may be used.

### EXAMPLES

To verify the invention, two test runs, both with control samples were prepared. In the test runs, the deposited films on quartz substrates were exposed to deionized water baths and tape tests, bath and tape tests performed on separate samples and control samples.

### Example 1—First Test Run

As the first test run, 8 quartz substrates were deposited with a first titanium oxide providing a titanium oxide layer having a thickness of 3 nm. On top of it, a ZnS layer with a thickness 200 nm was deposited. On top of the ZnS layer, an aluminium oxide layer with a thickness of 200 nm was deposited. Finally, on the aluminium oxide layer, a second titanium oxide layer was deposited having a thickness of 7 nm.

All the layers were deposited with the ALD method, in a Beneq P400 series ALD coating tool. The sample structure corresponds to FIG. 3.

For the first titanium oxide layer and second titanium oxide layer, the pulsing sequence at a process temperature (temperature in the reaction space of the ALD coating tool) of 130° C. was:
0.8 s pulse for TiCl₄ precursor (precursor for titanium),
3 s purge with an inert gas,
0.8 s pulse for H₂O precursor (first precursor for oxygen), and
3 s purge with an inter gas.

Pulsing sequence was carried out and repeated until a desired thickness for the first and second titanium oxide layer was reached (3 nm and 7 nm, respectively).

For the ZnS layer, the pulsing sequence at a process temperature (temperature in the reaction space of the ALD coating tool) of 130° C. was:
0.4 s pulse for H₂S precursor (precursor for sulphur),
6.8 s purge with an inert gas,
0.7 s pulse for DEZ precursor (diethylzinc; precursor for zinc), and
7.8 s purge with an inter gas.

Pulsing sequence was carried out and repeated until a desired thickness (200 nm) for the ZnS layer was reached.

For the aluminium oxide layer, the pulsing sequence at a process temperature (temperature in the reaction space of the ALD coating tool) of 130° C. was:
0.7 s pulse for H₂O precursor (second precursor for oxygen),
12.2 s purge with an inert gas,
0.9 s pulse for tri-methyl aluminium (TMA) precursor (precursor for aluminium), and
7 s purge with an inter gas.

Pulsing sequence was carried out and repeated until a desired thickness (200 nm) for the aluminium oxide layer was reached.

Control samples of 8 quartz substrates were identical, with the exception that the first titanium oxide layer arranged to improve adhesion was omitted.

Next, the 4 samples and 4 control samples were placed in a bath of room temperature (20 C) deionized water for 24 hours. After the bath, the samples were allowed to dry in a cleanroom environment.

Results were as follows:
For the samples, no delamination of the deposited film structure resulted.
For control samples (with no first titanium oxide adhesion layer), all samples exhibited mild to severe delamination of the film.

Next, tape tests were performed on the samples and control samples that were not exposed to deionized water bath. In these tests, a general-purpose office pressure sensitive colourless tape with a width of 19 mm (brand name “Scotch Magic”) was applied with moderate force pushing the tape on the surface for a length of approximately 20 mm, and then the tape was peeled off (one peeling lasting for approximately 1 s for the 20 mm length of tape).

Results were as follows:
For the samples, no delamination of the deposited wear-resistant optical film structure resulted.
For control samples (with no first titanium oxide adhesion layer), all samples exhibited mild to severe delamination of the film (in other words, substantial portions of the film deposited on the quartz substrate were attached on the tape coming off the surface of the quartz substrate).

To summarize, with the first titanium oxide layer with thickness 3 nm, the adhesion of the film structure of ZnS/aluminium oxide/titanium oxide was clearly improved to the quartz substrate compared to the adhesion without the thin 3 nm first titanium oxide layer. This validates the positive technical effect of the wear-resistant optical film 20.

### Example 2—Second Test Run

As the second test run, the first test run was repeated to a structure with no aluminium oxide layer and no second titanium oxide layer deposited. In other words, the samples had 3 nm (first) titanium oxide layer as an adhesion layer between the quartz substrate and the ZnS layer with thickness of 200 nm. Control samples had only the ZnS layer with thickness of 200 nm on the quartz substrate. Thus, the sample structure corresponds to FIG. 1. Eight sample substrates and eight control samples substrates were prepared.

The results were identical to the first test run in the sense that
with the 3 nm first titanium oxide adhesion layer, no peeling due to deionized water bath (water bath at room temperature of 20 C, duration of bath 24 h) in was observed among 4 samples,
whereas the 4 samples without the first titanium oxide adhesion layer exhibited mild to severe delamination of the ZnS layer after the 24 h bath.

The tape test was performed similarly as with the first test run, on the four samples and four control samples that were not exposed to deionized water bath. Results were very similar to the first test run:
for the samples, no delamination of the deposited film structure resulted in the tape tests, and
for the control samples (with no first titanium oxide adhesion layer), all samples exhibited mild to severe delamination of the film (in other words, substantial portions of the film were attached on the tape coming off the surface of the quartz substrate).

The invention has been described above with reference to the examples shown in the figures. However, the invention is in no way restricted to the above examples but may vary within the scope of the claims.

1.-25. (canceled)

26. A method for fabricating a wear-resistant optical film on a quartz substrate, wherein the wear-resistant optical film comprises a zinc sulphide layer and a first titanium oxide layer, the zinc sulphide layer arranged on the first titanium oxide layer, the wear-resistant optical film arranged on the quartz substrate, the first titanium oxide layer being arranged to improve the adhesion of the wear-resistant optical film to the quartz substrate, the method comprising the steps of:
a) depositing the first titanium oxide layer on the quartz substrate with alternately repeating surface reactions of at least two precursors including a precursor for titanium and a first precursor for oxygen for forming the first titanium oxide layer, and
b) depositing the zinc sulphide layer on the first titanium oxide layer with alternately repeating surface reactions of at least two precursors including a precursor for zinc and a precursor for sulphur for forming the zinc sulphide layer.

27. The method according to claim 26, wherein the wear-resistant optical film further comprises:
a second titanium oxide layer and
an aluminium oxide layer,
the second titanium oxide layer arranged on the aluminium oxide layer, and the aluminium oxide layer arranged on the zinc sulphide layer, the second titanium oxide layer and the aluminium oxide layer being arranged to decrease the water permeability of the wear-resistant optical film, the method further comprises the steps of:
c) depositing the aluminium oxide layer on the zinc sulphide layer with alternately repeating surface reactions of at least two precursors including a precursor for aluminium and a second precursor for oxygen for forming the aluminium oxide layer, and
d) depositing the second titanium oxide layer on the aluminium oxide layer with alternately repeating surface reactions of at least two precursors including the precursor for titanium and the first precursor for oxygen for forming the second titanium oxide layer.

28. The method according to claim 26, wherein the precursor for titanium is selected from a group consisting of titanium chloride, titanium bromide, and titanium iodide.

29. The method according to claim 26, wherein the precursor for titanium is selected:
from a group consisting of titanium ethoxide, titanium i-propoxide, and titanium t-butoxide; or
from a group consisting of tetrakis(dimethylamino)titanium, tetrakis(diethylamino)titaniumandtetrakis(ethylmethylamino)titanium.

30. The method according to claim 27, wherein the precursor for aluminium is selected from a group consisting of tri-methyl-aluminium, aluminium tri-chloride, aluminium isopropoxide and tris(dimethylamido)aluminium(III).

31. The method according to claim 26, wherein the precursor for sulphur is selected from a group consisting of hydrogen sulphide, di-tert-butyl disulphide and elemental sulphur vapor.

32. The method according to claim 26, wherein the precursor for zinc is selected from a group consisting of bis(pentafluorophenyl)zinc, bis(2,2,6,6-tetramethyl-3,5-heptanedionato)zinc(II), diethylzinc and diphenylzinc.

33. The method according to claim 26, wherein the first precursor for oxygen is selected:
from a group consisting of water, methanol, ethanol, propanol, isopropanol, butanol, 2-butanol, and tert-butanol; or
from a group consisting of ozone; and a combination comprising ozone.

34. The method according to claim 26, wherein the first precursor for oxygen is selected:
from a group consisting of a combination of ozone and water, a combination of ozone and oxygen, and a combination of ozone and hydrogen peroxide; or
from a group consisting of oxygen-containing radicals, oxygen plasma, carbon dioxide plasma, organic peroxides, organic hydroperoxides, peroxyacids, and singlet oxygen.

35. The method according to claim 27, wherein the second precursor for oxygen is selected:
from a group consisting of water, methanol, ethanol, propanol, isopropanol, butanol, 2-butanol, and tert-butanol; or
from a group consisting of ozone; and a combination comprising ozone.

36. The method according to claim 27, wherein the second precursor for oxygen is selected:
from a group consisting of a combination of ozone and water, a combination of ozone and oxygen, and a combination of ozone and hydrogen peroxide; or
from a group consisting of oxygen-containing radicals, oxygen plasma, carbon dioxide plasma, organic peroxides, organic hydroperoxides, peroxyacids, and singlet oxygen.

37. The method according to claim 26, wherein the steps of:
depositing the first titanium oxide layer, and
depositing the zinc sulphide layer are carried out at a temperature of 60-450° C.

38. The method according to claim 27, wherein the steps of:
depositing the aluminium oxide layer, and
depositing the second titanium oxide layer are carried out at a temperature of 60-450° C.

39. The method according to claim 26, wherein depositing the first titanium oxide layer is carried out until the thickness of the first titanium oxide layer is 1-10 nm.

40. The method according to claim 26, wherein depositing the zinc sulphide layer is carried out until the thickness of the zinc sulphide layer is 10-500 nm.

41. The method according to claim 27, wherein depositing the aluminium oxide layer is carried out until the thickness of the aluminium oxide layer is 100-300 nm.

42. The method according to claim 27, wherein depositing the second titanium oxide layer is carried out until the thickness of the second titanium oxide layer is 1-15 nm.

43. The wear-resistant optical film on a surface of a quartz substrate, wherein the wear-resistant optical film is obtained by a method of claim 26.

44. A wear-resistant optical film on a surface of a quartz substrate, wherein the wear-resistant optical film comprises a zinc sulphide layer and a first titanium oxide layer, the zinc sulphide layer provided on the first titanium oxide layer, and the first titanium oxide layer provided on the quartz substrate.

45. The wear-resistant optical film according to claim 44, wherein the wear-resistant optical film comprises:
an aluminium oxide layer deposited on the zinc sulphide layer, and
a second titanium oxide layer deposited on the aluminium oxide layer.

46. The wear-resistant optical film according to claim 44, wherein the thickness of the first titanium oxide layer is 1-10 nm.

47. The wear-resistant optical film according to claim 44, wherein the thickness of the zinc sulphide layer is 10-500 nm.

48. The wear-resistant optical film according to claim 45, wherein the thickness of the aluminium oxide layer is 100-300 nm.

49. The wear-resistant optical film according to claim 45, wherein the thickness of the second titanium oxide layer is 1-15 nm.

50. Use of a wear-resistant optical film according to claim 43 on at least one quartz substrate, wherein:
the at least one quartz substrate comprises at least one quartz area, and
the at least one quartz area is arranged at an outer surface of an optical device, and
the wear-resistant optical film is used for protecting the at least one quartz area against detrimental effects of environment.
